(19) United States
(12) Patent Application Publication
(10) Pub. No.: US 2026/0100212 A1
(43) Pub. Date: Apr. 9, 2026

(54) MAGNETIC MEMORY AND OPERATION METHOD OF THE SAME

(71) Applicant: Industrial Technology Research Institute, Hsinchu (TW)

(72) Inventors: Ziaur Rahaman Shakh, Hsinchu County (TW); Yao-Jen Chang, Yunlin County (TW); Jeng-Hua Wei, Taipei City (TW)

(73) Assignee: Industrial Technology Research Institute, Hsinchu (TW)

(21) Appl. No.: 18/981,631

(22) Filed: Dec. 15, 2024

(30) Foreign Application Priority Data
Oct. 9, 2024 (TW) 113138473

(51) Int. Cl. G11C 11/16; H10B 61/00; H10N 50/10

(52) U.S. Cl. CPC G11C 11/1675; G11C 11/1673; H10B 61/20; H10N 50/10

(57) ABSTRACT

A magnetic memory and an operation method thereof are provided. The magnetic memory includes a heavy metal layer and at least one magnetic tunnel junction (MTJ) formed on the heavy metal layer. The MTJ includes a free layer, a pinned layer, a tunneling barrier layer, a first diffusion barrier layer and a second diffusion barrier layer. The free layer is located on the heavy metal layer. The pinned layer is located on the free layer. The tunneling barrier layer is located between the free layer and the pinned layer. The first diffusion barrier layer is located between the tunneling barrier layer and the free layer. The second diffusion barrier layer is located between the tunneling barrier layer and the pinned layer. The magnetic memory has excellent reliability and significantly increases the number of cycles of memory write and erase functions.

### CROSS-REFERENCE TO RELATED APPLICATION

This application claims the priority benefit of Taiwan application serial no. 113138473, filed on Oct. 9, 2024. The entirety of the foregoing patent application is hereby incorporated by reference herein and made a part of this specification.

### TECHNICAL FIELD

The disclosure relates to a magnetic memory and an operation method thereof.

### BACKGROUND

Spin transfer torque magnetic random-access memory (STT-MRAM) is a kind of non-volatile magnetic memory based on spin transfer torque, which has significant advantages such as excellent non-volatility, high write and read speed, zero leakage power, and compatibility with advanced CMOS technology. In STT-MRAM, the magnetization of the free layer (FL) can be changed by applying a spin-polarized current directly through the MTJ cell without applying an external magnetic field, so there is no magnetic interference, which can achieve the characteristics of STT-MRAM with low power consumption and high density.

Although STT-MRAM has attracted considerable attention worldwide due to its unique features, some significant challenges have to be addressed before this technology being commercialized. The main challenges of STT-MRAM are reliability, including read interference, read and write errors, and possible non-conducting tunnel barrier breakdown due to the same read/write access paths. The reliability of STT-MRAM can indeed be improved if the write current does not pass through the thin non-conducting tunnel barrier layer.

The spin-orbit torque (SOT) MRAM with a separated read and write path has been studied extensively in recent years as a potential candidate for further improving the reliability of STT-MRAM. The main benefit of SOT-MRAM over STT-MRAM is that the read and write paths are independent, which principally solves the problems of reliability and non-conducting tunnel barrier breakdown issues, provides a new pathway for cache memory applications.

In the typical SOT-MRAM, a transverse pure-spin current is generated due to the spin-orbit coupling (SOC) effects at the bulk of the nonmagnetic heavy metal (HM) layer and/or the interface of the heavy-metal/ferromagnetic (FM) layer. When a charge current is injected into the HM layer of the three-terminal MTJ-based memory cells, a transverse pure-spin current is generated due to the spin-Hall effect and/or interface Rashba effect. The accumulation of spin-polarized electrons at the interface of the HM/FM layer exerts a spin-orbit torque on the FM layer that can switch the magnetization of the FM free-layer of MTJ.

SOT plus STT switching has recently been investigated to achieve reliable switching in low power electrical measurements. However, a reliability problem occurred during the cycling measurements of SOT plus STT switching of SOT-MRAM technology. To achieve reliable switching in low-power electrical measurements in SOT-MRAM devices, there is a need in the technology for innovative structures that enable improved SOT-MRAM technology.

### SUMMARY

The disclosure provides a magnetic memory. The magnetic memory of the disclosure includes a heavy metal layer and at least one magnetic tunnel junction (MTJ) formed on the heavy metal layer. The MTJ includes a free layer, a pinned layer, a tunneling barrier layer, a first diffusion barrier layer, and a second diffusion barrier layer. The free layer is located on the heavy metal layer. The pinned layer is located on the free layer. The tunneling barrier layer is located between the free layer and the pinned layer. The first diffusion barrier layer is located between the tunneling barrier layer and the free layer. The second diffusion barrier layer is located between the tunneling barrier layer and the pinned layer.

The disclosure also provides an operation method of a magnetic memory. The operation method of the magnetic memory of the disclosure at least includes: a write operation is performed on the MTJ that has been selected, and a recovery operation is performed on the MTJ that has been selected. The writing operation includes applying a first write voltage to the heavy metal layer, and applying a second write voltage to the pinned layer. The recovery operation includes applying a recovery voltage to the pinned layer or the heavy metal layer. The recovery voltage is greater than the second write voltage.

### BRIEF DESCRIPTION OF THE DRAWINGS

FIG. 1 is a perspective schematic diagram of a magnetic memory according to an embodiment of the disclosure.

FIG. 2 is a circuit diagram of performing a SOT plus STT switching operation by taking the magnetic memory in FIG. 1 as an example.

FIG. 3 is a current-voltage relationship diagram of an operation method of a magnetic memory according to an embodiment of the disclosure.

FIG. 4 is a circuit diagram of a memory array composed of the magnetic memory in FIG. 1.

### DETAILED DESCRIPTION OF DISCLOSED EMBODIMENTS

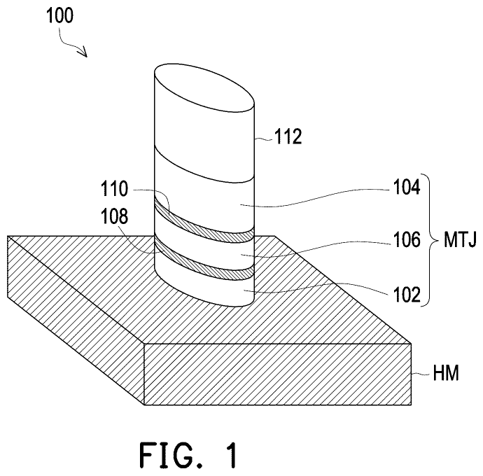

FIG. 1 is a perspective schematic diagram of a magnetic memory 100 according to an embodiment of the disclosure.

Please refer to FIG. 1. The magnetic memory 100 of the embodiment includes a heavy metal layer HM and at least one magnetic tunnel junction MTJ formed on the heavy metal layer HM. In some embodiments, the heavy metal layer HM may be tantalum (Ta), tungsten (W), platinum (Pt), palladium (Pd), hafnium (Hf), niobium (Nb), molybdenum (Mo), gold (Au) or alloys thereof, but the disclosure is not limited thereto. The magnetic tunnel junction MTJ may include a free layer 102, a pinned layer 104, a tunneling barrier layer 106, a first diffusion barrier layer 108, and a second diffusion barrier layer 110. The free layer 102 is located on the heavy metal layer HM. In some embodiments, the free layer 102 may be a single layer or a composite layer. The single layer may be iron (Fe), cobalt (Co), nickel (Ni), gadolinium (Gd), terbium (Tb), cobalt iron boron (CoFeB) alloy or cobalt iron (CoFe) alloy, but the material of the single layer is not limited thereto. The composite layer may be a combination of cobalt iron boron (CoFeB) alloy, tantalum (Ta) and cobalt iron boron (CoFeB) alloy, or a combination of cobalt iron (CoFe) alloy, tantalum (Ta) and cobalt iron (CoFe), but the material combination of the composite layer is not limited thereto. The pinned layer 104 is located above the free layer 102. The pinned layer 104 is a magnetic layer with a constant magnetic torque and may be made of any material as the foregoing free layer 102, but the disclosure is not limited thereto. In some embodiments, the pinned layer 104 may be a single layer or a composite layer. The single layer may be cobalt iron (CoFe) alloy, cobalt iron boron (CoFeB) alloy or cobalt nickel (CoNi) alloy, but the material of the single layer is not limited thereto. The composite layer may be a combination of cobalt (Co) layer/platinum (Pt) layer, cobalt (Co) layer/nickel (Ni) layer, or cobalt (Co) layer/palladium (Pd) layer, but the material of the composite layer is not limited thereto. The tunneling barrier layer 106 is located between the free layer 102 and the pinned layer 104. In some embodiments, the material of the tunneling barrier layer 106 may be magnesium oxide (MgO), aluminum oxide (AlOx), aluminum nitride (AlNx), strontium titanate (SrTiO₃), or a combination thereof, but the disclosure is not limited thereto.

The first diffusion barrier layer 108 is located between the tunneling barrier layer 106 and the free layer 102. The second diffusion barrier layer 110 is located between the tunneling barrier layer 106 and the pinned layer 104. In some embodiments, the first diffusion barrier layer 108 is in direct contact with the tunneling barrier layer 106. Therefore, an entire upper surface of the first diffusion barrier layer 108 may contact a bottom surface of the tunneling barrier layer 106. In some embodiments, the second diffusion barrier layer 110 is in direct contact with the tunneling barrier layer 106. Therefore, an entire lower surface of the second diffusion barrier layer 110 may contact a top surface of the tunneling barrier layer 106.

A storage function of a magnetic memory often experiences a drop in the resistance value after repeated write/erase operations on the magnetic memory. For example, a magnetic memory without the first diffusion barrier layer 108 and the second diffusion barrier layer 110 may experience a sudden drop in the resistance value after a few cycles of performing the SOT plus STT switching, which means that the original memory function of the magnetic memory has failed. On the contrary, for the magnetic memory with the first diffusion barrier layer 108 and the second diffusion barrier layer 110, the number of write/erase cycles of the magnetic memory 100 may be increased to more than 10⁶ times. This is because the first diffusion barrier layer 108 and the second diffusion barrier layer 110 can prevent metal and/or oxygen ions or vacancies from entering the tunneling barrier layer 106.

More specifically, the first diffusion barrier layer 108 may prevent metal ions and/or oxygen ions or vacancies in the free layer 102 from diffusing to the tunneling barrier layer 106 after multiple write/erase operations. The second diffusion barrier layer 110 may prevent metal ions and/or oxygen ions or vacancies in the pinned layer 104 from diffusing to the tunneling barrier layer 106 after multiple write/erase operations. The metal ions and/or oxygen ions or vacancies can originally penetrate into the tunneling barrier layer 106 due to the influence of the current during several write/erase operations, resulting in the generation of a strong current path, and allowing a high current flow, leading to a sudden drop in the resistance value of the tunneling barrier layer 106, which originally has insulating properties, especially a suddenly drop in the resistance value of the magnetic tunnel junction MTJ, that leads to a memory failure.

More specifically, the diffusion barrier layer (that is, the first diffusion barrier layer 108 and the second diffusion barrier layer 110) in the embodiment has the effect of preventing metal ions and/or oxygen ions or vacancies from entering the tunneling barrier layer 106, which can ensure that the memory states are maintained during write/erase cycling operations to improve the reliability of the magnetic memory 100. In some embodiments, the free layer 102 may be composed of cobalt iron boron (CoFeB) alloy, the pinned layer 104 may be composed of cobalt iron boron (CoFeB) alloy, and the tunneling barrier layer 106 may be a magnesium oxide (MgO) film. In some embodiments, the thickness of the first diffusion barrier layer 108 may be less than 1 nm, such as less than 0.9 nm, less than 0.8 nm, less than 0.7 nm, or less than 0.5 nm. In some embodiments, the thickness of the second diffusion barrier layer 110 may be less than 1 nm, such as less than 0.9 nm, less than 0.8 nm, less than 0.7 nm, or less than 0.5 nm. More specifically, the thickness of the first diffusion barrier layer 108 and the thickness of the second diffusion barrier layer 110 just need to be able to prevent metal and/or oxygen ions or vacancies from diffusing to the tunneling barrier layer 106, such as the thickness of several atoms or thicker.

In some embodiments, the first diffusion barrier layer 108 and the second diffusion barrier layer 110 may be metal layers. The materials thereof may individually include iron (Fe), tantalum nitride (TaN), ruthenium (Ru) or tungsten (W), but the disclosure is not limited thereto. In some embodiments, the first diffusion barrier layer 108 and the second diffusion barrier layer 110 may be metal oxide layers. The materials thereof may individually include titanium oxide (TiOx), tungsten oxide (WOx), tantalum oxide (TaOx) or ruthenium oxide (RuOx), but the disclosure is not limited thereto. More specifically, materials that are able to prevent metal and/or oxygen ions or vacancies in the pinned layer 104 and the free layer 102 from diffusing to the tunneling barrier layer 106 are basically selected for the first diffusion barrier layer 108 and the second diffusion barrier layer 110. Therefore, even if the first diffusion barrier layer 108 and the second diffusion barrier layer 110 are metal layers and/or metal oxide layers, materials that are difficult to diffuse and are able to block metal and/or oxygen ions or vacancies in the pinned layer 104 and the free layer 102 are selected.

Data writing of the magnetic memory 100 is implemented through converting the magnetism of the free layer 102. Therefore, the free layer 102 may be regarded as a storage layer of a memory cell. The method for data reading of the magnetic memory 100 is to measure a magnetoresistance of the magnetic tunnel junction MTJ by applying current or voltage through the magnetic tunnel junction MTJ at the vertical direction from top to bottom of the magnetic memory 100. The level of a tunnel magnetoresistance (TMR) is determined by directions of magnetic torques of the free layer 102 and the pinned layer 104. That is to say, if the magnetic torques of the free layer 102 and the pinned layer 104 are parallel and in the same direction, the current value of the data reading is 1. If the magnetic torques of the two are parallel but in opposite directions, the current value of the data reading is 0. In the embodiment, the magnetic memory 100 may further include an upper electrode 112 that is connected to the pinned layer 104 of the magnetic tunnel junction MTJ.

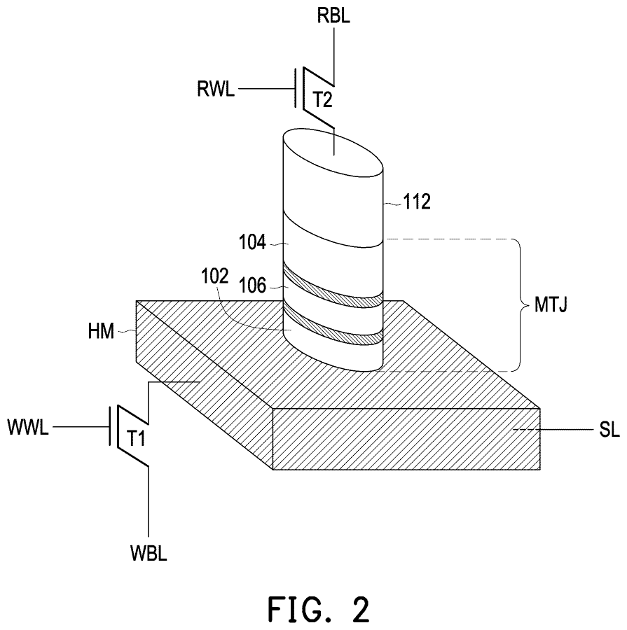

FIG. 2 is a circuit diagram of performing a SOT plus STT switching operation by taking the magnetic memory 100 in FIG. 1 as an example.

In FIG. 2, if a write operation is to be performed on the magnetic tunnel junction MTJ that has been selected, a first write voltage may be applied to the heavy metal layer HM through turning on a first transistor T1, and a second write voltage may be applied to the pinned layer 104 through turning on a second transistor T2. That is, in the writing operation, the first write voltage is applied to the heavy metal layer HM at a horizontal direction, and the second write voltage is applied to the pinned layer 104 at a vertical direction from top to bottom of the magnetic memory. Since the write operation involves simultaneously the current path passing through the upper electrode 112 to the magnetic tunnel junction MTJ and the current path flowing through the heavy metal layer HM, the write current may be reduced, comparing with the write operation performed simply by passing through the heavy metal layer HM. More specifically, the current from the upper electrode 112 to the magnetic tunnel junction MTJ may assist the free layer 102 to switch, so that the current passing through the heavy metal layer HM is reduced. For example, the write operation of a magnetic memory originally needs a write current of 3 mA. Through the embodiment, it may be changed to a SOT plus STT switching operation. At this time, the write current may be reduced to about 1.5 mA, but the disclosure is not limited thereto. Once the write current is reduced, the magnetic memory may achieve the effect of low power operations.

In FIG. 2, if a read operation is to be performed on the magnetic tunnel junction MTJ that has been selected, a read voltage may be applied to the pinned layer 104 by turning on the second transistor T2 as in normal operations. That is, in the writing operation, in the read operation, read voltage may be applied to the pinned layer 104 at the vertical direction from top to bottom of the magnetic memory. At the same time, the first transistor T1 is turned off. Based on whether a ferromagnetic layer (that is, the free layer 102 and the pinned layer 104) of the magnetic tunnel junction MTJ has a parallel magnetization direction (that is, the magnetic tunnel junction MTJ is in a low resistance state) or has an anti-parallel magnetization direction (that is, the magnetic tunnel junction MTJ is in a high resistance state), the magnetic tunnel junction MTJ may have different resistance values. This variable resistance value may affect the value of a read current or the value of a voltage drop of the magnetic tunnel junction MTJ. Therefore, bit data (that is, resistance state) stored in the magnetic tunnel junction MTJ may be read.

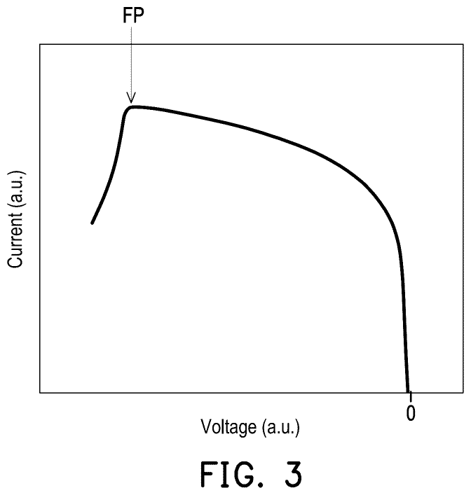

In FIG. 2, if a recovery operation is to be performed on the magnetic tunnel junction MTJ that has been selected, a recovery voltage may be applied to the pinned layer 104 by turning on the second transistor T2 or to the heavy metal layer HM by turning on the first transistor T1. That is, in the recovery operation, the recovery voltage is applied to the pinned layer 104 at the vertical direction from top to bottom of the magnetic memory, or to the heavy metal layer HM at the vertical direction from bottom to top of the magnetic memory. The foregoing recovery voltage is greater than the foregoing second write voltage to allow a large current to enter the magnetic tunnel junction MTJ from the upper electrode 112 and remove the metal and/or oxygen ions or vacancies diffused to the tunneling barrier layer 106. In some embodiments, when the method of performing a recovery operation on the magnetic tunnel junction MTJ is performed for an electrical detection on a failed memory element, a relationship between a voltage and a current is found as shown in FIG. 3. For an example, in a range where the voltage is OV to about-0.5V, there is a tendency for the current to become greater and greater, which means that there is an undesirable increase in current in this voltage range. However, after the voltage exceeds-0.5V (which may be called a failure point FP), the current is found to sharply drop, and the tunnel magnetoresistance (TMR) may accordingly increase and return to the original characteristics of the magnetic memory. Therefore, applying a greater voltage allows the large current to enter the magnetic tunnel junction MTJ from the upper electrode 112, and the effect of recovering the characteristics of the magnetic memory may be achieved.

In some embodiments, the foregoing first write voltage is greater than the foregoing second write voltage, and the recovery voltage is greater than the second write voltage. In some embodiments, the foregoing recovery operation may be periodically performed to remove metal and/or oxygen ions or vacancies that might diffuse to the tunneling barrier layer 106 at regular intervals. In other embodiments, the foregoing recovery operation may be performed after the resistance value of the magnetic tunnel junction MTJ suddenly drops in an anti-parallel magnetization state or in a parallel magnetization state, that is, after the magnetic tunnel junction MTJ fails.

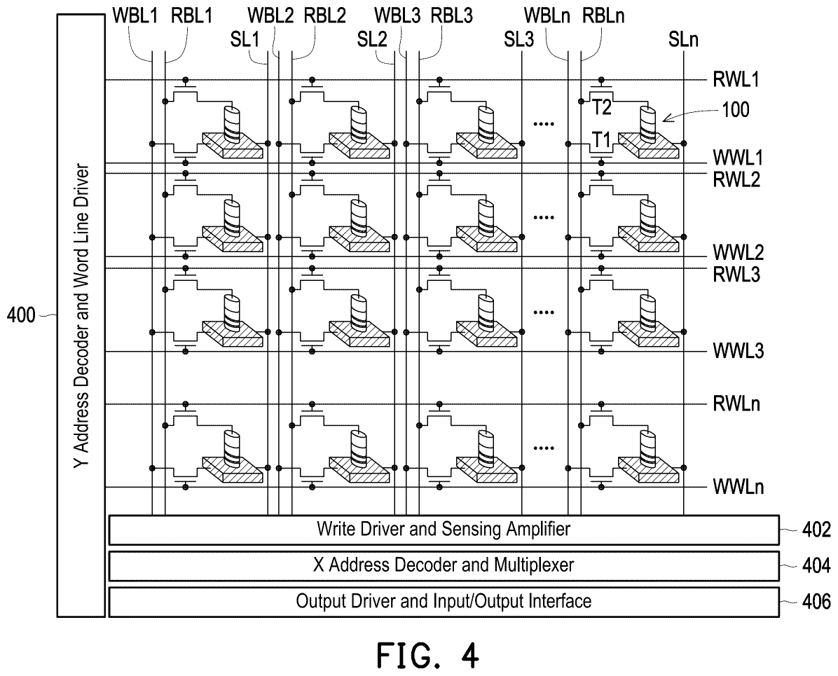

FIG. 4 is a circuit diagram of a memory array composed of the multiple magnetic memories 100 in FIG. 1. Relevant materials, configurations, dimensions and/or operations described in FIG. 1 and FIG. 2 may be utilized in the following embodiments, and detailed descriptions thereof are omitted.

In FIG. 4, read bit lines RBL1, RBL2, RBL3 . . . and RBLn, write bit lines WBL1, WBL2, WBL3 . . . and WBLn, and source lines SL1, SL2, SL3 . . . and SLn extend in a column direction (lateral/horizontal direction). Read word lines RWL1, RWL2, RWL3 . . . and RWLn and write word lines WWL1, WWL2, WWL3 . . . and WWLn extend in a row direction (longitudinal/vertical direction). Each magnetic memory is respectively disposed at a location defined by the foregoing read bit lines, the write bit lines, the write word lines, the read word lines and the source lines. For example, the magnetic memory in the upper right corner of FIG. 4 is the magnetic memory 100 in FIG. 1. The magnetic memory 100 is disposed at a location defined by the read bit line RBLn, the write bit line WBLn, the write word line WWL1, the read word line RWL1 and the source line SLn.

In the embodiment of FIG. 4, magnetic memories that are vertically adjacent along the row direction (longitudinal/vertical direction) are coupled in pairs to the same read bit line RBL1, RBL2, RBL3 . . . or RBLn and the same write bit line WBL1, WBL2, WBL3 . . . or WBLn. Magnetic memories that are horizontally adjacent along the column direction (lateral/horizontal direction) are coupled to the same write word line WWL1, WWL2, WWL3 . . . or WWLn and the same read word line RWL1, RWL2, RWL3 . . . or RWLn. Magnetic memories that are vertically adjacent along the row direction (longitudinal/vertical direction) may share the same source line SL1, SL2, SL3 . . . or SLn.

The read word lines RWL1, RWL2, RWL3 . . . and RWLn and the write word lines WWL1, WWL2, WWL3 . . . and WWLn are coupled to a Y address decoder and word line driver 400. The source lines SL1, SL2, SL3 . . . and SLn are coupled a current source circuit (not shown). The read bit lines RBL1, RBL2, RBL3 . . . and RBLn and the write bit lines WBL1, WBL2, WBL3 . . . and WBLn are coupled to a write driver and sensing amplifier 402, and may be coupled to an output driver and input/output interface 406 through an X address decoder and multiplexer 404.

As for details of the circuit diagram of the magnetic memory coupled to the foregoing lines, as shown in FIG. 2, one end of the heavy metal layer HM is coupled to the corresponding source line SL, and the other end of the heavy metal layer HM is coupled to the corresponding write bit line WBL through the first transistor T1. A gate of the first transistor T1 is coupled to the corresponding write word line WWL. The upper electrode 112 located on a top part of the magnetic tunnel junction MTJ is coupled to the corresponding read bit line RBL through the second transistor T2. A gate of the second transistor T2 is coupled to the corresponding read word line RWL. The read word line RWL may also turn on the second transistor T2 to provide a write current during a write operation.

The magnetic memory according to the disclosure has excellent reliability and significantly increases the number of cycles of memory write and erase functions. According to the operation method of a magnetic memory of the disclosure, not only a spin-transfer torque (STT) switching may be executed by a spin-orbit-torque (SOT) magnetic memory to allow a write current of the memory to be reduced to achieve the effect of low power operations. A recovery operation of the magnetic memory without the diffusion barrier layer may also be performed to recover the tunneling barrier layer in a failed memory or a memory that is about to fail to the original characteristics of a resistance values to maintain a normal operation of the memory.

Although the disclosure has been disclosed in the above embodiments, the embodiments are not intended to limit the disclosure. Persons skilled in the art may make some changes and modifications without departing from the spirit and scope of the disclosure. Therefore, the protection scope of the disclosure shall be defined by the appended claims.

What is claimed is:

1. A magnetic memory, comprising: a heavy metal layer and at least one magnetic tunnel junction (MTJ) formed on the heavy metal layer, wherein:
the at least one MTJ comprises:
a free layer, located on the heavy metal layer;
a pinned layer, located on the free layer;
a tunneling barrier layer, located between the free layer and the pinned layer;
a first diffusion barrier layer, located between the tunneling barrier layer and the free layer; and
a second diffusion barrier layer, located between the tunneling barrier layer and the pinned layer.

2. The magnetic memory according to claim 1, wherein the first diffusion barrier layer is in direct contact with the tunneling barrier layer.

3. The magnetic memory according to claim 1, wherein the second diffusion barrier layer is in direct contact with the tunneling barrier layer.

4. The magnetic memory according to claim 1, wherein a thickness of the first diffusion barrier layer is less than 1 nm.

5. The magnetic memory according to claim 1, wherein a thickness of the second diffusion barrier layer is less than 1 nm.

6. The magnetic memory according to claim 1, wherein the first diffusion barrier layer and the second diffusion barrier layer are metal layers or metal oxide layers.

7. The magnetic memory according to claim 6, wherein materials of the first diffusion barrier layer and the second diffusion barrier layer individually comprise iron (Fe), tantalum nitride (TaN), ruthenium (Ru) or tungsten (W).

8. The magnetic memory according to claim 6, wherein materials of the first diffusion barrier layer and the second diffusion barrier layer individually comprise titanium oxide (TiOx), tungsten oxide (WOx), tantalum oxide (TaOx) or ruthenium oxide (RuOx).

9. The magnetic memory according to claim 1, further comprising an upper electrode that is connected to the pinned layer of the at least one MTJ.

10. An operation method of the magnetic memory according to claim 1, comprising:
performing a write operation to the at least one MTJ that has been selected, comprising: applying a first write voltage to the heavy metal layer and applying a second write voltage to the pinned layer; and
performing a recovery operation to the at least one MTJ that has been selected, comprising: applying a recovery voltage to the pinned layer or the heavy metal layer, wherein the recovery voltage is greater than the second write voltage.

11. The operation method of the magnetic memory according to claim 10, wherein the first write voltage is greater than the second write voltage, and the recovery voltage is greater than the first write voltage.

12. The operation method of the magnetic memory according to claim 10, wherein the recovery operation is performed after a resistance value of the at least one MTJ in an anti-parallel magnetization state suddenly drops.

13. The operation method of the magnetic memory according to claim 10, wherein the recovery operation is periodically performed.

14. The operation method of the magnetic memory according to claim 10, further comprising: performing a read operation to the at least one MTJ that has been selected, and the read operation comprises applying a read voltage to the pinned layer.
